(19) United States
(12) Patent Application Publication
(10) Pub. No.: US 2014/0071638 A1
(43) Pub. Date: Mar. 13, 2014

(54) INTEGRAL DATA LINE STORAGE STRUCTURE OF DIGITAL DEVICE

(71) Applicant: SHENZHEN LUXSHARE PRECISION INDUSTRY CO., LTD., Shenzhen (CN)

(72) Inventors: Huabing LI, Shenzhen (CN); Guangqing ZHANG, Shenzhen (CN); Peng LIAO, Shenzhen (CN); Xiangpiao YANG, Shenzhen (CN)

(73) Assignee: SHENZHEN LUXSHARE PRECISION INDUSTRY CO., LTD., Shenzhen (CN)

(21) Appl. No.: 13/677,779

(22) Filed: Nov. 15, 2012

(30) Foreign Application Priority Data
Sep. 11, 2012 (CN) 201220460548.0

(51) Int. Cl. H05K 7/00

(52) U.S. Cl. CPC H05K 7/00
USPC 361/749; 361/679.01

(57) ABSTRACT

An integral data line storage structure of a digital device relates to the technical field of digital devices, and in particular, to improvements of a data connection line storage structure of a digital device such as a mobile hard disk, a multimedia player, a DV, a digital camera, a mobile phone, a tablet computer, an MP4, or a recorder pen, so as to solve the technical disadvantage that the data connection line matching the existing digital device is inconvenient to carry and store. The integral data line storage structure of a digital device includes a digital device body and a data connection line connected to the digital device body. The data connection line is of a flat shape through injection molding, and a wiring groove for receiving the data connection line when not used is disposed on the digital device body. When not used, the data connection line may be received in the wiring groove, so that the data connection line and the digital device body form a unity, which is convenient to carry, has a compact overall structure, and achieves good dustproof effect.

### BACKGROUND OF THE DISCLOSURE

1. Field of the Disclosure

The disclosure relates to the technical field of digital devices, and in particular, to improvements of a data connection line storage structure of a digital device such as a mobile hard disk, a multimedia player, a DV, a digital camera, a mobile phone, a tablet computer, an MP4, or a recorder pen.

2. Related Art

At present, a digital device available on the market needs to be provided with a data connection line to implement data transmission. The data connection line and the digital device are two separate parts. The data connection line is inconvenient to carry and store and is easily lost or forgotten. In this case, the digital device cannot be connected to an external device for data transmission.

### SUMMARY OF THE DISCLOSURE

In sum, the main objective of the disclosure is to solve the technical disadvantage that the data connection line matching the existing digital device is inconvenient to carry and store, and provide an integral data line storage structure of a digital device.

In order to solve the technical problem provided by the disclosure, the adopted technical solution is an integral data line storage structure of a digital device, including a digital device body and a data connection line connected to the digital device body. The data connection line is of a flat shape through injection molding, and a wiring groove for receiving the data connection line when not used is disposed on the digital device body.

A further improvement of the technical solution of the disclosure includes the following content.

The line material of the data connection line is a Flexible Printed Circuit (FPC), a Flexible Flat Cable (FFC), or an oblate cable.

A connector at a head end of the data connection line is a USB2.0, USB3.0, VGA DVI, RJ11, RJ45, HDMI DP, MINI DP, MICRO USB, or MINI USB plug connector.

A tail end of the data connection line is directly welded to the digital device body, or a plug connector disposed at the tail end of the data connection line is inserted into a USB2.0, USB3.0, VGA DVI, RJ11, RJ45, HDMI DP, MINI DP, MICRO USB, or MINI USB receptacle connector disposed on the digital device body.

The connectors at the head end and the tail end of the data connection line are disposed at the same side of the line material of the data connection line, and connector slots for retaining the connectors at the head end and the tail end of the data connection line are disposed at two ends of the bottom of the wiring groove.

A slot and a block retained thereby are disposed between a side wall of the connector at the tail end of the data connection line and the connector slot.

The digital device body is a mobile hard disk, a multimedia player, a DV, a digital camera, a mobile phone, a tablet computer, an MP4, or a recorder pen.

The beneficial effect of the disclosure is as follows. The data connection line used in the disclosure is of a flat shape through injection molding, and the wiring groove for receiving the data connection line when not used is disposed on the digital device body. When not used, the data connection line may be received in the wiring groove, so that the data connection line and the digital device body form a unity, which is convenient to carry, has a compact overall structure, and achieves good dustproof effect. The disclosure is applicable to a digital device provided with a data connection line, such as a mobile hard disk, a multimedia player, a DV, a digital camera, a mobile phone, a tablet computer, an MP4, or a recorder pen. The data connection line may be a USB2.0, USB3.0, VGA DVI, RJ11, RJ45, HDMI DP, MINI DP, MICRO USB, or MINI USB data connection line.

### BRIEF DESCRIPTION OF THE DRAWINGS

FIG. 1 is a schematic three-dimensional structural view of the disclosure before use;

FIG. 2 is a schematic structural view of a USB3.0 data connection line of the disclosure removed from a case;

FIG. 3 is a schematic exploded structural view of the disclosure;

FIG. 4 is a schematic structural view of the USB3.0 data connection line of the disclosure before injection molding;

FIG. 5 is a schematic structural view of the USB3.0 data connection line of the disclosure after injection molding for the first time;

FIG. 6 is a schematic structural view of the USB3.0 data connection line of the disclosure after injection molding for the second time; and

FIG. 7 is a schematic structural view of the USB3.0 data connection line of the disclosure with a block disposed at a side wall of a micro usb3.0 plug at a tail end.

### DETAILED DESCRIPTION OF THE DISCLOSURE

The structure of the disclosure is further described in combination with the accompanying drawings by taking an example that a digital device body of the disclosure is a USB3.0 mobile hard disk.

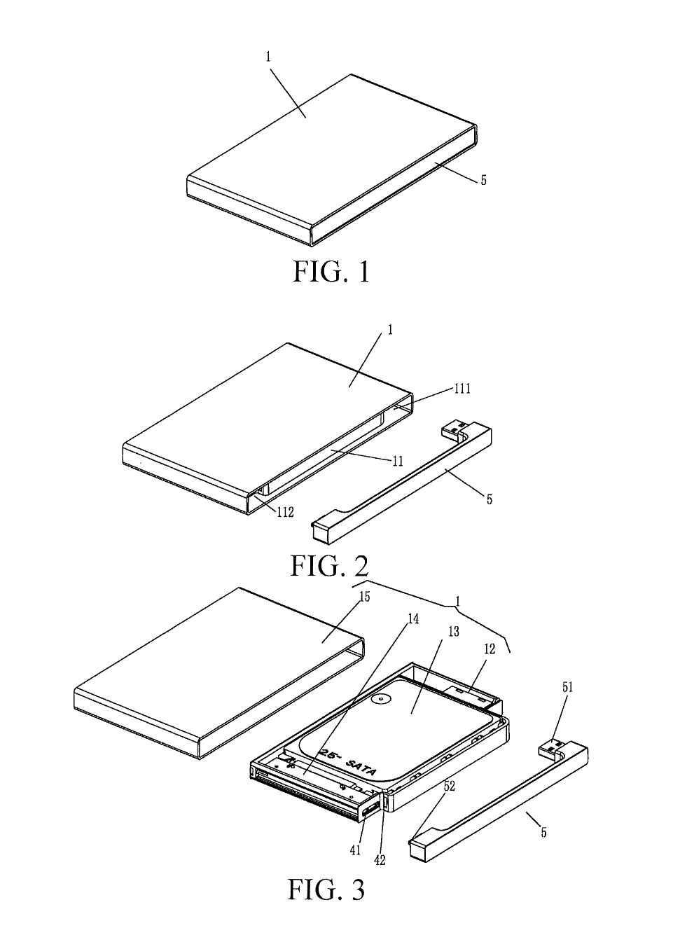

Referring to FIG. 1, FIG. 2, and FIG. 3, the disclosure is formed by a digital device body 1 and a data connection line 5. The digital device body is a USB3.0 mobile hard disk. The data connection line 5 is of a flat shape through injection molding. A wiring groove 11 matching the data connection line 5 is disposed on the digital device body 1. The data connection line 5 is received in the wiring groove 11 to form a unity with the digital device body 1.

The digital device body 1 includes a case 15, a hard disk holder 12, a hard disk body 13, and an interface module 14. The hard disk holder 12 is disposed in the case 15, the hard disk body 13 is disposed in the hard disk holder 12, and the interface module 14 is connected to the hard disk body 13.

The interface module 14 is used to convert an interface of the hard disk body 13 into a USB3.0 interface output. The type of the interface module 14 depends on the type of the interface of the hard disk body 13. For example, the hard disk body 13 is a 2.5-inch SATA hard disk with an SATA2 interface, a solid state disk with an MSATA interface, and the like. When the hard disk body 13 is a 2.5-inch SATA hard disk with an SATA2 interface, the interface module 14 is an SATA-USB3.0 conversion module.

The data connection line 5 is a USB3.0 data connection line. The data connection line 5 is connected to the hard disk body 13 and a USB interface of a computer through the interface module 14, so as to establish data transmission between the hard disk body 13 and the computer. A head end of the data connection line 5 is connected to a USB3.0 male connector 51, for being inserted in a USB3.0 female interface of the computer. In order to enhance the generality of the disclosure, the interface module 14 includes a micro usb3.0 receptacle 41 used in a conventional USB3.0 mobile hard disk. A tail end of the data connection line 5 is disposed with a micro usb3.0 plug 52, and the micro usb3.0 plug 52 is inserted into the micro usb3.0 receptacle 41, so that it is convenient to replace the USB3.0 data connection line 5 and also convenient to use the conventional USB3.0 data connection line or a data line of an existing micro usb2.0 plug through connection.

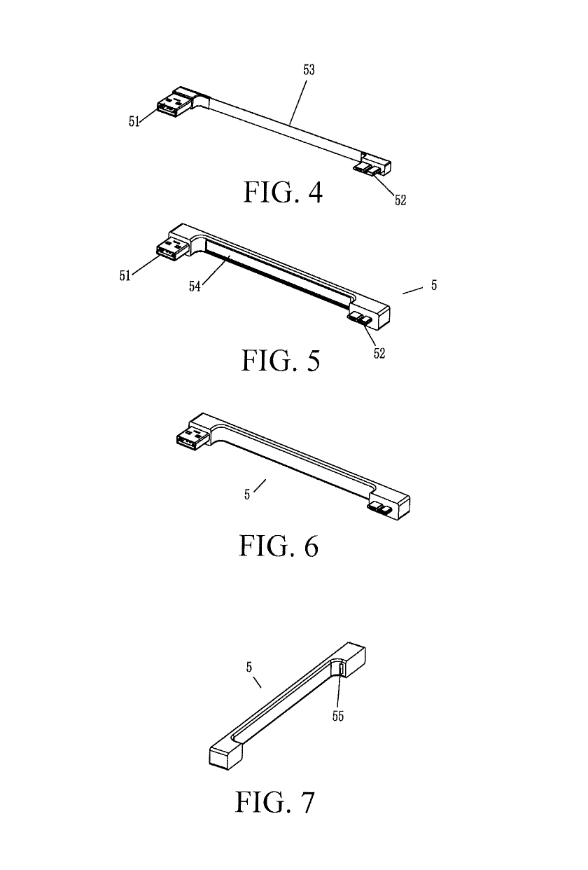

Referring to FIG. 1, FIG. 4, FIG. 5, and FIG. 6, since the number of strands of the USB3.0 data connection line is large and the volume of the digital device body 1 is small, the length of the USB3.0 data connection line is limited, that is, the line material of the conventional USB3.0 data connection line lacks flexibility and thus cannot be used in the structure of the disclosure. The line material 53 of the USB3.0 data connection line 5 of the disclosure is an FPC, an FFC, a PCB, or an oblate cable. The micro usb3.0 plug 52 and the USB3.0 male connector 51 at the head end and the tail end of the USB3.0 data connection line 5 are located at the same side of the USB3.0 data connection line 5 and are vertically connected to the USB3.0 data connection line. Connector slots 111 and 112 for retaining the connectors 51 and 52 at the head end and the tail end of the data connection line 5 are disposed at two ends of the bottom of the wiring groove 11. As shown in FIG. 3 and FIG. 7, in order to reduce the disconnection of the micro usb3.0 plug 52 from the micro usb3.0 receptacle 41 in use, a slot 42 and a block 55 retained thereby are disposed between a side wall of the micro usb3.0 plug 52 at the tail end of the USB3.0 data connection line 5 and the hard disk holder 12.

The USB3.0 data connection line 5 provided by the disclosure has an integrated structure fabricated by using a secondary forming technology. As shown in FIG. 4, first, the micro usb3.0 plug 52 and the USB3.0 male connector 51 are vertically welded to two ends of the line material 53 respectively. Then, injection molding for integration is performed for the first time, to obtain a structure shown in FIG. 5, that is, a groove 54 not injection molded is formed at the same side of the line material 53 as the micro usb3.0 plug 52 and the USB3.0 male connector 51, and at the other side of the line material 53, the tail ends of the micro usb3.0 plug 52 and the USB3.0 male connector 51 are encapsulated.

Finally, injection molding for integration is performed for the second time, to obtain a final product shown in FIG. 6, that is, injection molding and encapsulation are mainly performed on the groove 54.

The above is only one of the embodiments exemplified by the disclosure. During specific implementation, the digital device body may also be a device including a data connection line, such as a multimedia player, a DV, a digital camera, a mobile phone, a tablet computer, an MP4, or a recorder pen. According to the different digital device bodies, the connector at the head end of the data connection line may be correspondingly a

USB2.0, USB3.0, VGA DVI, RJ11, RJ45, HDMI DP, MINI DP, MICRO USB, or MINI USB plug connector.

The tail end of the data connection line can be directly welded to the digital device body, or according to the different digital device bodies, corresponding connectors are selected for insertion. For example, a plug connector disposed at the tail end of the data connection line is inserted into a USB2.0, USB3.0, VGA DVI, RJ11, RJ45, HDMI DP, MINI DP, MICRO USB, or MINI USB receptacle connector disposed on the digital device body. The data connection line 5 may be formed by injection molding once or multiple times. The line material and the connector are integrally formed, which adapts to all plastic materials. A PCB may also be added between the line material and the connector for adaptation.

1. An integral data line storage structure of a digital device, comprising a digital device body and a data connection line connected to the digital device body, wherein the data connection line is of a flat shape through injection molding, and a wiring groove for receiving the data connection line when not used is disposed on the digital device body.

2. The integral data line storage structure of a digital device according to claim 1, wherein the line material of the data connection line is a Flexible Printed Circuit (ITC), a Flexible Flat Cable (ITC), or an oblate cable.

3. The integral data line storage structure of a digital device according to claim 1, wherein a connector at a head end of the data connection line is a USB2.0, LISB3.0, VGA DVI, RJ11, RJ45, HDMI DP, MINI DP, MICRO USB, or MINI USB plug connector.

4. The integral data line storage structure of a digital device according to claim 1, wherein a tail end of the data connection line is directly welded to the digital device body, or a plug connector disposed at the tail end of the data connection line is inserted into a USB2.0, USB3.0, VGA DVI, RJ11, R45, HDMI DP, MINI DP, MICRO USB, or MINI USB receptacle connector disposed on the digital device body.

5. The integral data line storage structure of a digital device according to claim 4, wherein the connectors at the head end and the tail end of the data connection line are disposed at the same side of the line material of the data connection line, and connector slots for retaining the connectors at the head end and the tail end of the data connection line are disposed at two ends of the bottom of the wiring groove.

6. The integral, data line storage structure of a digital device according to claim 5, wherein a slot and a block retained thereby are disposed between a side wall of the connector at the tail end of the data connection line and the connector slot.

7. The integral data line storage structure of a digital device according to claim 1, wherein the digital device body is a mobile hard disk, a multimedia player, a DV, a digital camera, a mobile phone, a tablet computer, an MP4, or a recorder pen.

8. The integral data line storage structure of a digital device according to claim 3, wherein a tail end of the data connection line is directly welded to the digital device body, or a plug connector disposed at the tail end of the data connection line is inserted into a USB2.0, USB3.0, VGA DVI, RJ11, RJ45, HDMI DP, MINI DP, MICRO USB, or MINI USB receptacle connector disposed on the digital device body.
